(19) United States
(12) Patent Application Publication
(10) Pub. No.: US 2026/0282961 A1
(43) Pub. Date: Sep. 17, 2026

(54) PACKAGE COMPRISING A BRIDGE WITH A BRIDGE ALIGNMENT STRUCTURE

(71) Applicant: QUALCOMM Incorporated, San Diego, CA (US)

(72) Inventors: Yujen CHEN, Taichung (TW); Yangyang SUN, San Diego, CA (US)

(21) Appl. No.: 19/080,534

(22) Filed: Mar. 14, 2025

(51) Int. Cl. H01L 23/538; H01L 23/498; H01L 23/544

(52) U.S. Cl. CPC H10W 70/65; H10W 46/00; H10W 70/611; H10W 90/701; H10W 46/301

(57) ABSTRACT

A package comprising a metallization portion comprising at least one dielectric layer; and a plurality of metallization interconnects; a bridge comprising a bridge alignment structure, wherein the bridge is located at least partially in the metallization portion; a first integrated device coupled to the bridge and the metallization portion; and a second integrated device coupled to the bridge and the metallization portion.

### FIELD

Various features relate to packages and bridges.

### BACKGROUND

A package may include a substrate and integrated devices. These components are coupled together to provide a package that may perform various electrical functions. There is an ongoing need to provide better performing packages. Moreover, there is also an ongoing need to reduce and/or minimize the overall size of the packages.

### SUMMARY

Various features relate to packages and bridges.

One example provides a package comprising a metallization portion comprising at least one dielectric layer; and a plurality of metallization interconnects; a bridge comprising a bridge alignment structure, wherein the bridge is located at least partially in the metallization portion; a first integrated device coupled to the bridge and the metallization portion; and a second integrated device coupled to the bridge and the metallization portion.

Another example provides a package comprising a metallization portion comprising at least one dielectric layer; and a plurality of metallization interconnects; a bridge located at least partially in the metallization portion; a first integrated device coupled to the bridge and the metallization portion, wherein the first integrated device comprises a first alignment structure; and a second integrated device coupled to the bridge and the metallization portion.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes integrated devices, a metallization portion and a bridge comprising an alignment structure.

FIG. 2 illustrates a close up view of a package that includes integrated devices, a metallization portion and a bridge comprising an alignment structure.

FIG. 3 illustrates an exemplary cross sectional profile view of a bridge comprising an alignment structure.

FIG. 4 illustrates an exemplary cross sectional profile view of an integrated device comprising an alignment structure.

FIG. 5 illustrates an exemplary cross sectional plan view of a package that includes integrated devices, a metallization portion and a bridge comprising an alignment structure.

FIGS. 6A-6B illustrate an exemplary sequence for fabricating a package that includes integrated devices, a metallization portion and a bridge comprising an alignment structure.

FIG. 7 illustrates an exemplary flow diagram of a method for fabricating a package that includes integrated devices, a metallization portion and a bridge comprising an alignment structure.

FIGS. 8A-8B illustrate an exemplary sequence for fabricating a metallization portion with a bridge comprising an alignment structure.

FIG. 9 illustrates an exemplary flow chart of a method for fabricating a metallization portion with a bridge comprising an alignment structure.

FIGS. 10A-10C illustrate an exemplary sequence for fabricating an integrated device comprising an alignment structure.

FIG. 11 illustrates an exemplary flow chart of a method for fabricating an integrated device comprising an alignment structure.

FIG. 12 illustrates an exemplary sequence for fabricating a bridge comprising an alignment structure.

FIG. 13 illustrates an exemplary flow chart of a method for fabricating a bridge comprising an alignment structure.

FIG. 14 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a metallization portion comprising at least one dielectric layer; and a plurality of metallization interconnects; a bridge comprising a bridge alignment structure, wherein the bridge is located at least partially in the metallization portion; a first integrated device coupled to the bridge and the metallization portion; and a second integrated device coupled to the bridge and the metallization portion. The first integrated device and the second integrated device may each include an alignment structure. The bridge alignment structure and/or the alignment structure(s) of the integrated device(s) may help ensure the proper connection between the integrated devices and the bridge, which helps provide a robust and reliable package. This may help improve the performance of the package.

### Exemplary Package Comprising a Bridge With an Alignment Structure

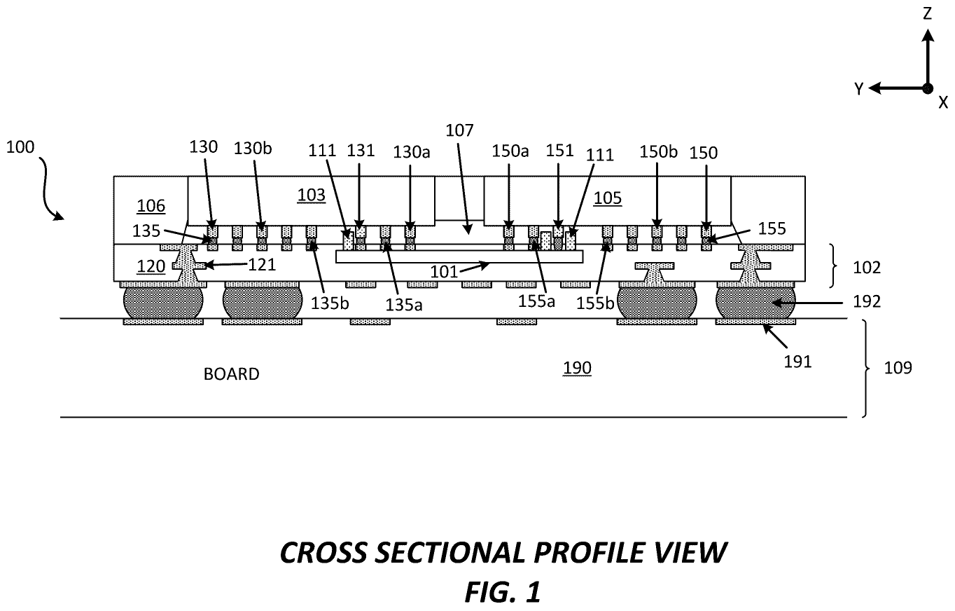

FIG. 1 illustrates a cross sectional profile view of a package 100 that includes a bridge with a bridge alignment structure. The package 100 is coupled to a board 109 through a plurality of solder interconnects 192. The board 109 includes at least one board dielectric layer 190 and a plurality of board interconnects 191. The board 109 may include a printed circuit board (PCB). In some implementations, the package 100 may be coupled to a substrate (e.g., laminated substrate, coreless substrate, cored substrate) instead of the board 109. The package 100 may include a bridge 101, a metallization portion 102, an integrated device 103, an integrated device 105 and an encapsulation layer 106. The package 100 may also include an underfill 107.

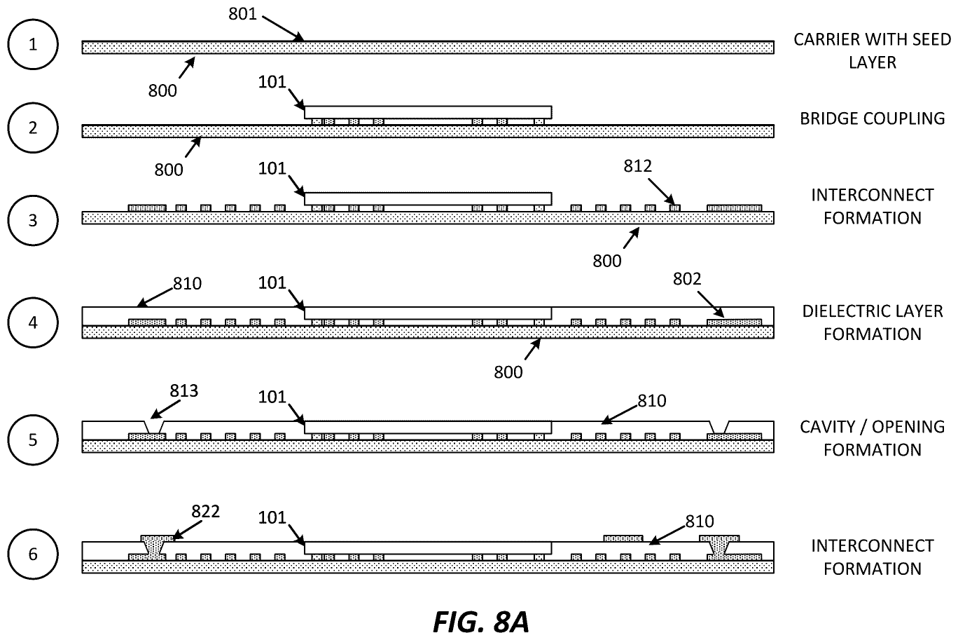

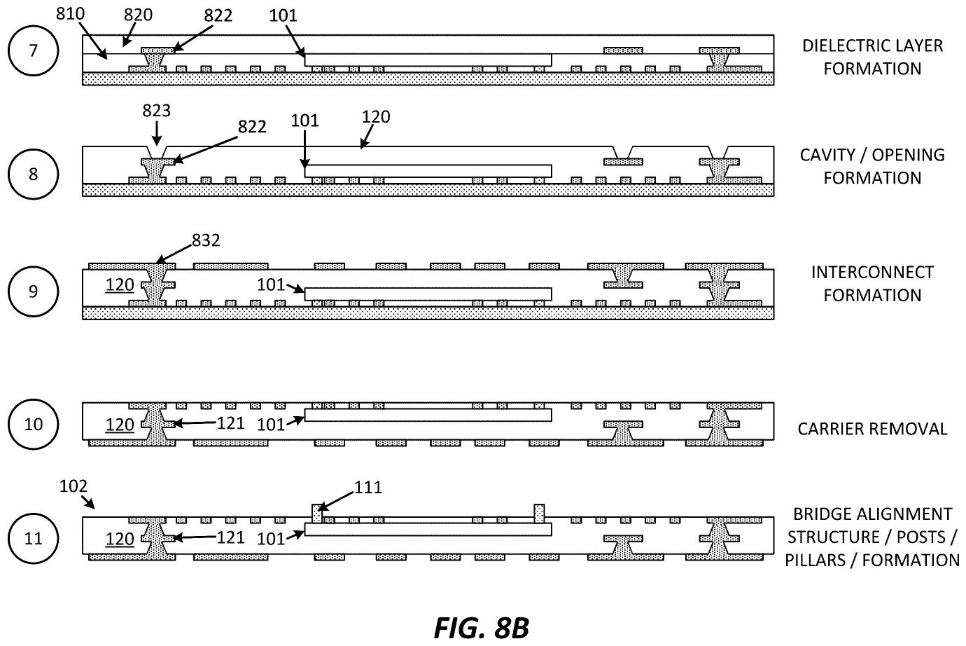

The metallization portion 102 includes at least one dielectric layer 120 and a plurality of metallization interconnects 121. The metallization portion 102 may be a redistribution portion. The plurality of metallization interconnects 121 may include a plurality of redistribution interconnects. The metallization portion 102 may also include the bridge 101. The bridge 101 may be located at least partially in the metallization portion 102. Thus, the bridge 101 may be at least partially embedded in the metallization portion 102. The bridge 101 may touch the at least one dielectric layer 120 of the metallization portion 102. An example of fabricating the metallization portion 102 that includes the bridge 101 is illustrated and described below in at least FIGS. 8A-8B.

The metallization portion 102 may include a redistribution portion. The plurality of metallization interconnects 121 may include a plurality of redistribution interconnects. A redistribution interconnect may include portions that have a U-shape or V-shape. The terms “U-shape” and “V-shape” shall be interchangeable. The terms “U-shape” and “V-shape” may refer to the side profile shape of the interconnects, metallization interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). In some implementations, a process for fabricating redistribution interconnects may form the U-shape interconnect (or the V-shape interconnect).

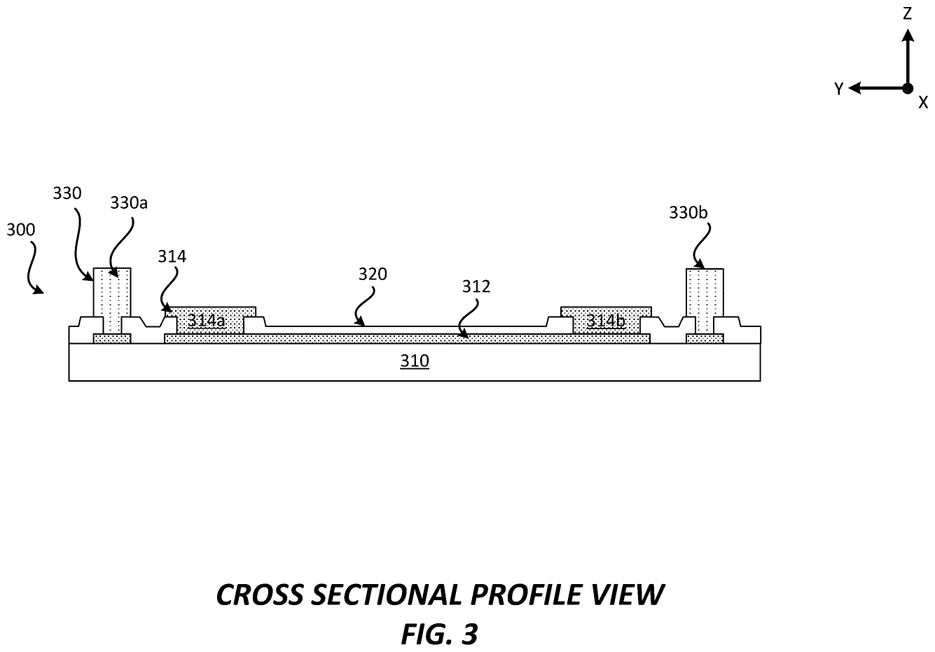

The bridge 101 may include a bridge alignment structure 111 and a plurality of bridge interconnects. As will be further described below, the bridge alignment structure may include at least one bridge pillar interconnects that may be located in different portions of the bridge 101. The bridge alignment structure 111 may be free of an electrical connection with transistors of the integrated device 103 and transistors of the integrated device 105. A more detailed example of a bridge with a bridge alignment structure is illustrated and described below in at least FIG. 3.

In some implementations, the integrated device 103 may be a first integrated device. In some implementations, the integrated device 103 may be a second integrated device. The integrated device 103 is coupled to the metallization portion 102 and the bridge 101. The integrated device 103 may include a plurality of pillar interconnects 130 and an alignment structure 131. The alignment structure 131 may include at least one alignment pillar. The plurality of pillar interconnects 130 may include a plurality of pillar interconnects 130a and a plurality of pillar interconnects 130b. The integrated device 103 may be coupled to the plurality of bridge interconnects of the bridge 101 through the plurality of pillar interconnects 130a and a plurality of solder interconnects 135a. The integrated device 103 may be coupled to the plurality of metallization interconnects 121 of the metallization portion 102 through a plurality of pillar interconnects 130b and a plurality of solder interconnects 135b. The alignment structure 131 may be free of an electrical connection with transistors of the integrated device 103.

In some implementations, the integrated device 105 may be a first integrated device. In some implementations, the integrated device 105 may be a second integrated device. The integrated device 105 is coupled to the metallization portion 102 and the bridge 101. The integrated device 105 may include a plurality of pillar interconnects 150 and an alignment structure 151. The alignment structure 151 may include at least one alignment pillar. The plurality of pillar interconnects 150 may include a plurality of pillar interconnects 150a and a plurality of pillar interconnects 150b. The integrated device 105 may be coupled to the plurality of bridge interconnects of the bridge 101 through the plurality of pillar interconnects 150a and a plurality of solder interconnects 155a. The integrated device 105 may be coupled to the plurality of metallization interconnects 121 of the metallization portion 102 through a plurality of pillar interconnects 150b and a plurality of solder interconnects 155b. The alignment structure 151 may be free of an electrical connection with transistors of the integrated device 105.

The underfill 107 may be located between the integrated device 103 and the metallization portion 102. The underfill 107 may be located between the integrated device 103 and the bridge 101. The underfill 107 may at least partially encapsulate the plurality of pillar interconnects 130, the alignment structure 131, the plurality of solder interconnects 135 and/or the bridge alignment structure 111.

The underfill 107 may be located between the integrated device 105 and the metallization portion 102. The underfill 107 may be located between the integrated device 105 and the bridge 101. The underfill 107 may at least partially encapsulate the plurality of pillar interconnects 150, the alignment structure 151, the plurality of solder interconnects 155 and/or the bridge alignment structure 111.

The encapsulation layer 106 may be coupled to the metallization portion 102. The encapsulation layer 106 may at least partially encapsulate the integrated device 103, the integrated device 105 and/or the underfill 107. The encapsulation layer 106 may include a mold, a resin, an epoxy and/or a filler. The encapsulation layer 106 may include a different material from the underfill 107.

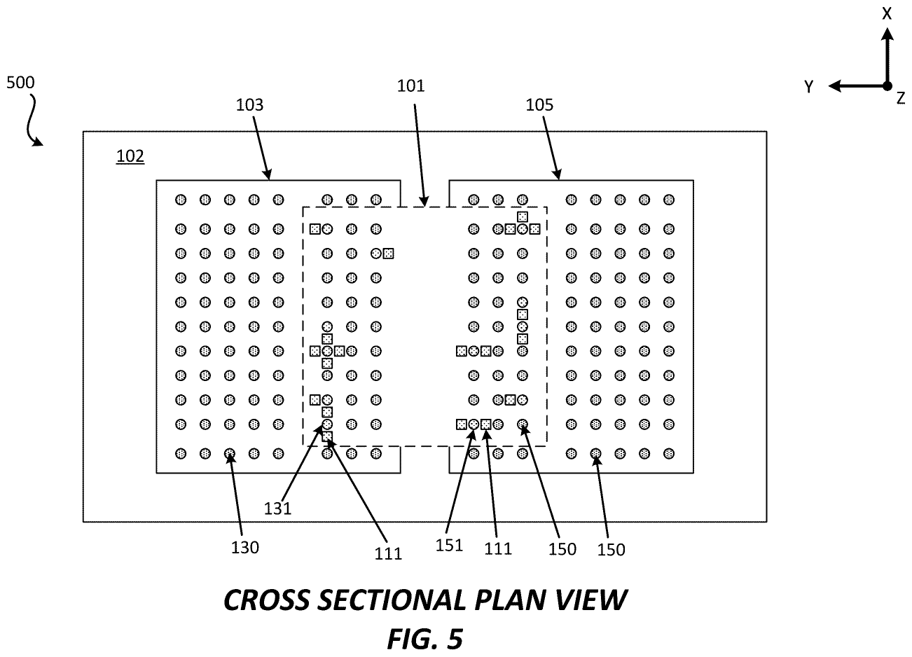

In some implementations, the use of the bridge alignment structure 111, the alignment structure 131 and/or the alignment structure 151 reduces, minimizes and/or eliminates misalignments between various interconnects of various components. In some implementations, the use of the bridge alignment structure 111, the alignment structure 131 and/or the alignment structure 151 helps provide reliable and/or accurate joints and/or connections, which helps provide reliable electrical paths between the various components of the package 100. This in turn, helps provide an improved and higher performing package in a compact form factor. Various examples of how alignment structures for the bridge and/or for integrated devices, may be configured are illustrated and described below in at least FIG. 5.

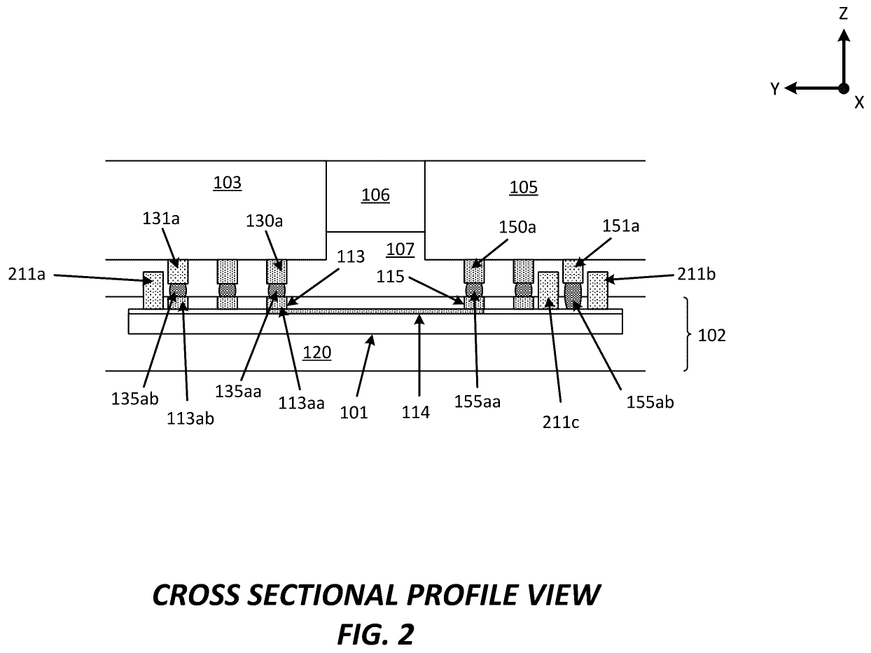

FIG. 2 illustrates a close up view of the package 100 of FIG. 1. As shown in FIG. 2, the bridge 101 is located at least partially in the metallization portion 102. The bridge 101 includes a plurality of bridge interconnects 113, a plurality of bridge interconnects 114, a plurality of bridge interconnects 115, a bridge alignment pillar 211a, a bridge alignment pillar 211b and a bridge alignment pillar 211c. The plurality of bridge interconnects 114 may be coupled to the plurality of bridge interconnects 113 and the plurality of bridge interconnects 115. The bridge alignment pillar 211a, the bridge alignment pillar 211b and/or the bridge alignment pillar 211c may be considered part of the bridge alignment structure 111. The bridge alignment pillar 211a, the bridge alignment pillar 211b and the bridge alignment pillar 211c may be free of an electrical connection with transistors of the integrated device 103 and transistors of the integrated device 105.

The integrated device 103 is coupled to the bridge 101. The integrated device 103 is coupled to the plurality of bridge interconnects 113 through the plurality of pillar interconnects 130a and the plurality of solder interconnects 135aa. The alignment pillar 131a may be coupled to the bridge interconnect 113ab through a solder interconnect 135ab. The bridge interconnect 113ab may be a dummy bridge interconnect. Thus, the bridge interconnect 113ab does not provide an electrical path to/from the integrated device 105. The alignment pillar 131a of the integrated device 103 may be directly adjacent to the bridge alignment pillar 211a of the bridge 101. In some implementations, the alignment pillar 131a of the integrated device 103 may touch the bridge alignment pillar 211a of the bridge 101. As will be further described below, the integrated device 103 may include more than one alignment pillar arranged in different locations and/or positions. Similarly, as will be further described below, the bridge 101 may include more than one bridge alignment pillar arranged in different locations and/or positions.

The integrated device 105 is coupled to the bridge 101. The integrated device 105 is coupled to the plurality of bridge interconnects 115 through the plurality of pillar interconnects 150a and the plurality of solder interconnects 155aa. The alignment pillar 151a may be coupled to the bridge 101 through a solder interconnect 155ab. The solder interconnect 155ab may be a dummy solder interconnect. The alignment pillar 151a of the integrated device 105 may be directly adjacent to the bridge alignment pillar 211b of the bridge 101. In some implementations, the alignment pillar 151a of the integrated device 105 may touch the bridge alignment pillar 211 b of the bridge 101.The alignment pillar 151a of the integrated device 105 may be directly adjacent to the bridge alignment pillar 211c of the bridge 101. In some implementations, the alignment pillar 151c of the integrated device 105 may touch the bridge alignment pillar 211b of the bridge 101. The alignment pillar 151a may be located laterally between the bridge alignment pillar 211b and the bridge alignment pillar 211c. Although not shown, a bridge alignment pillar may be located laterally between two or more alignment pillars from an integrated device. As will be further described below, the integrated device 105 may include more than one alignment pillar arranged in different locations and/or positions. Similarly, as will be further described below, the bridge 101 may include more than one bridge alignment pillar arranged in different locations and/or positions.

FIG. 3 illustrates an exemplary cross sectional profile view of a bridge 300 that includes a bridge alignment structure. The bridge 300 includes a bridge substrate 310, a plurality of bridge interconnects 312, a plurality of bridge interconnects 314, a bridge alignment structure 330 and a dielectric layer 320. The dielectric layer 320 may be a passivation layer. The bridge 300 may be an example of the bridge 101 of the disclosure. The bridge substrate 310 may include silicon (e.g., bridge silicon substrate). The plurality of bridge interconnects 312 may include bridge trace interconnects. The plurality of bridge interconnects 314 are coupled to the plurality of bridge interconnects 312. The plurality of bridge interconnects 314 may include bridge pad interconnects (e.g.,, 314a, 314b). The bridge alignment structure 330 may include a bridge alignment pillar 330a and a bridge alignment pillar 330b. The bridge alignment pillar 330a and/or the bridge alignment pillar 330b may have a height that is greater than the height of the bridge pad interconnect 314a and/or the bridge pad interconnect 314b. As will be further described below, the height of the bridge alignment structure 330 may be formed before or after the bridge 300 is embedded in a metallization portion.

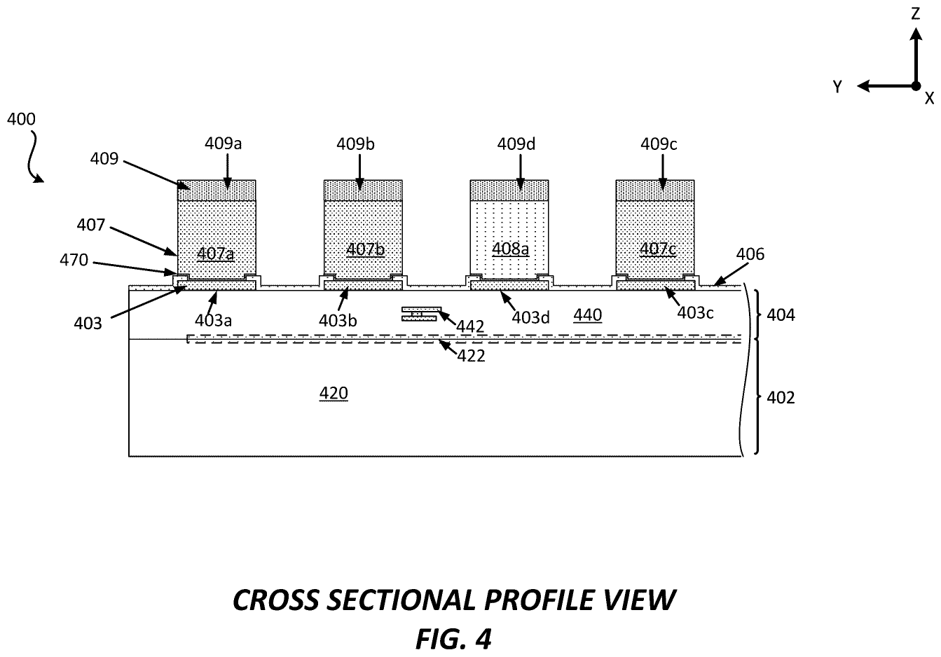

FIG. 4 illustrates a cross sectional profile view of an integrated device 400 that includes at least one alignment pillar. The integrated device 400 may represent the integrated device 103 and/or the integrated device 105. The integrated device 400 includes a die substrate portion 402, and a die interconnection portion 404. The die substrate portion 242 includes a die substrate 420 and an active region 422. The active region 422 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 422 of the die substrate 420. The die substrate 420 may include silicon.

The die interconnection portion 404 includes at least one dielectric layer 440 and a plurality of die interconnects 442. The die interconnection portion 404 is coupled to the die substrate portion 402. The plurality of die interconnects 442 are coupled to the active region 422 of the die substrate portion 402. In some implementations, a back end of line (BEOL) process may be used to fabricate the die interconnection portion 404.

The integrated device 400 includes a plurality of pad interconnects 403 and a passivation layer 406. The plurality of pad interconnects 403 and/or the passivation layer 406 may be coupled to the die interconnection portion 404. The plurality of pad interconnects 403 are coupled to the plurality of die interconnects 442. In some implementations, the plurality of pad interconnects 403 and/or the passivation layer 406 may be considered part of the die interconnection portion 404. The plurality of pad interconnects 403 include a pad interconnect 403a, a pad interconnect 403b, a pad interconnect 403c and a pad interconnect 403d.

The integrated device 400 includes a plurality of pillar interconnects 407, at least one pillar interconnect 408, a plurality of solder interconnects 409. The plurality of pillar interconnects 407 include a pillar interconnect 407a, a pillar interconnect 407b, a pillar interconnect 407c. The plurality of solder interconnects 409 include a solder interconnect 409a, a solder interconnect 409b, a solder interconnect 409c and a solder interconnect 409d. The plurality of pillar interconnects 407 may be coupled to and touch the plurality of pad interconnects 403. The plurality of solder interconnects 409 may be coupled to and touch the plurality of pillar interconnects 407. The plurality of pillar interconnects 407 may include a seed layer 470. The seed layer 470 may be an under bump metallization interconnect. In some implementations, the under bump metallization interconnect may be considered part of the plurality of pillar interconnects 407.

The at least one pillar interconnect 408 may include a pillar interconnect 408a. The at least one pillar interconnect 408 may be configured as an alignment structure for the integrated device 400. The at least one pillar interconnect 408 may be at least one alignment pillar. The alignment structure may include one or more pillar interconnects. The at least one pillar interconnect 408 is free of electrical connections with the transistors of the integrated device 400. The pillar interconnect 408a may be coupled to the solder interconnect 409d and the pad interconnect 403d. The pad interconnect 403d may be a dummy pad interconnect that is free of an electrical connection with transistors of the integrated device 400. The at least one pillar interconnect 408 may represent the alignment pillar 131a and/or the alignment pillar 151a.

FIG. 5 illustrates an exemplary cross sectional plan view of the package 500 that includes the metallization portion 102, the integrated device 103, the integrated device 105 and the bridge 101. FIG. 5 illustrates example of positions and/or locations of (i) the bridge alignment structure 111 of the bridge 101, (ii) the alignment structure 131 of the integrated device 103 and (iii) the alignment structure 151 of the integrated device 105. The bridge alignment structure 111 includes a plurality of bridge alignment pillars. The alignment structure 131 includes a plurality of alignment pillars (e.g., integrated device alignment pillars). The alignment structure 151 includes a plurality of alignment pillars (e.g., integrated device alignment pillars).

As shown in FIG. 5, the bridge alignment pillars may be located in the corners of the bridge 101 and in internal sections of the bridge 101. The bridge alignment pillars may be located directly adjacent to alignment pillars of integrated devices. In some implementations, a bridge alignment pillar may be located laterally between two alignment pillars of an integrated device (e.g., 103, 105). In some implementations, two or more bridge alignment pillars may laterally surround one alignment pillar of an integrated device. For example, an alignment pillar from an integrated device may be located laterally between two or more bridge alignment pillars. FIG. 5 illustrates that the bridge alignment structure 111 has having bridge alignment pillars with square planar shapes (e.g., shape along X-Y plane). However, these planar shapes are exemplary. The bridge alignment pillars may have other planar shapes, such as a circular planar shapes. In some implementations, some bridge alignment pillars may have a square planar shape and some bridge alignment pillars may have a circular planar shapes.

An integrated device (e.g., 103, 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc...). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one or more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103, 105) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G, 6G). The packages (e.g., 100) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

### Exemplary Sequence for Fabricating an Package Comprising an Alignment Structure

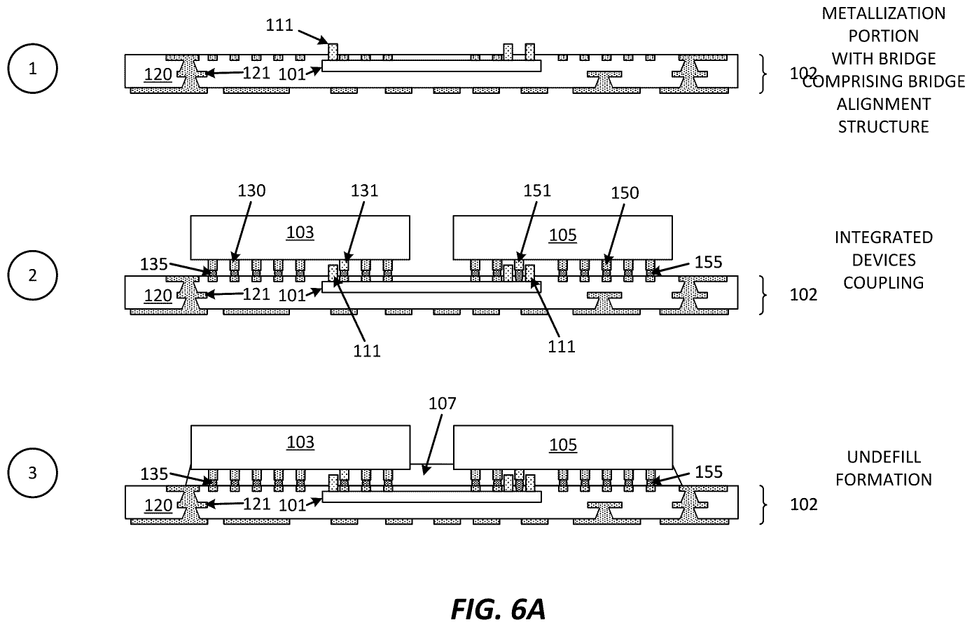

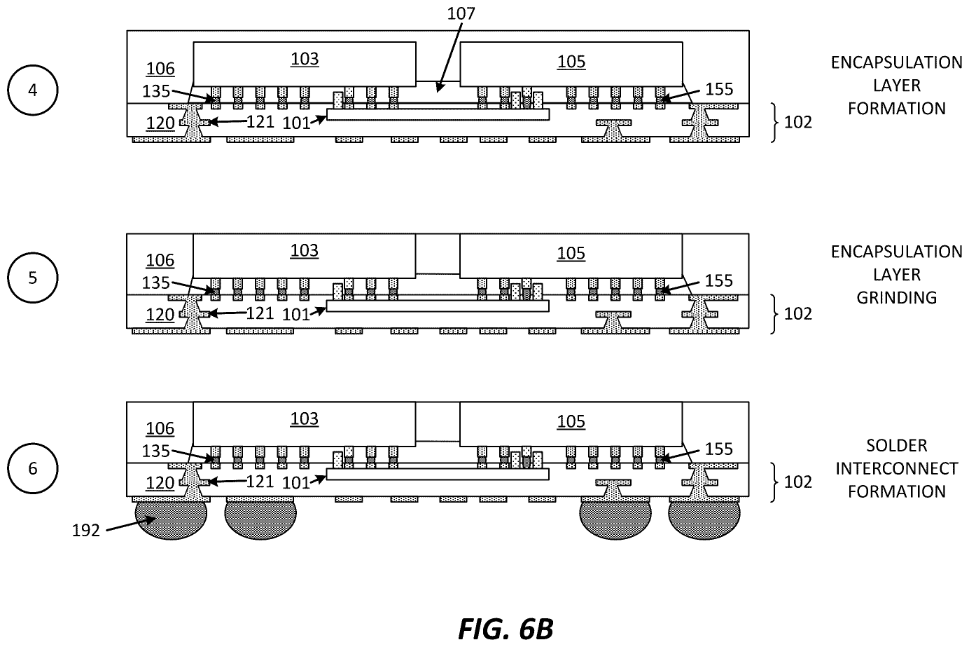

In some implementations, fabricating a package includes several processes. FIGS. 6A-6B illustrate an exemplary sequence for providing or fabricating a package comprising an alignment structure. In some implementations, the sequence of FIGS. 6A-6B may be used to provide or fabricate the package 100. However, the process of FIGS. 6A-6B may be used to fabricate any package described in the disclosure.

It should be noted that the sequence of FIGS. 6A-6B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 6A, illustrates a state after a metallization portion 102 is provided. The metallization portion 102 may include a bridge 101 that includes a bridge alignment structure 111. The bridge 101 may be located at least partially in the metallization portion 102. The metallization portion 102 may include at least one dielectric layer 120 and a plurality of metallization interconnects 121. An example of a process for fabricating a metallization portion 102 that includes the bridge 101 is illustrated and described below in at least FIGS. 8A-8B.

Stage 2 illustrates a state after the integrated device 103 and the integrated device 105 are coupled to the metallization portion 102 and the bridge 101. The integrated device 103 includes an alignment structure 131. The alignment structure 131 and the bridge alignment structure 111 help align the integrated device 103 with the metallization portion 102 and the bridge 101 during placement and coupling of the integrated device 103 to the metallization portion 102 and the bridge 101. The integrated device 103 may be coupled to the metallization portion 102 and the bridge 101 through a plurality of pillar interconnects 130 and a plurality of solder interconnects 135. A solder reflow process may be used to couple the integrated device 103 to the plurality of pillar interconnects 130 and the plurality of solder interconnects 135.

The integrated device 105 includes an alignment structure 151. The alignment structure 151 and the bridge alignment structure 111 help align the integrated device 105 with the metallization portion 102 and the bridge 101 during placement and coupling of the integrated device 105 to the metallization portion 102 and the bridge 101. The integrated device 105 may be coupled to the metallization portion 102 and the bridge 101 through a plurality of pillar interconnects 150 and a plurality of solder interconnects 155. A solder reflow process may be used to couple the integrated device 105 to the plurality of pillar interconnects 150 and the plurality of solder interconnects 155.

Stage 3 illustrates a state after an underfill 107 is provided, formed and/or dispensed. The underfill 107 may be formed between (i) the integrated device 103 and (ii) the metallization portion 102 and the bridge 101. The underfill 107 may be formed between (i) the integrated device 105 and (ii) the metallization portion 102 and the bridge 101. The underfill 107 may be located between the integrated device 103 and the integrated device 105. The underfill 107 may at least partially encapsulate the plurality of pillar interconnects 130, the plurality of solder interconnects 135, the plurality of pillar interconnects 150, the plurality of solder interconnects 155, the alignment structure 131 and/or the alignment structure 151.

Stage 4, as shown in FIG. 6B, illustrates a state after an encapsulation layer 106 is formed. The encapsulation layer 106 may at least partially encapsulate the integrated device 103, the integrated device 105 and/or the underfill 107. The encapsulation layer 106 may be coupled to the metallization portion 102. The encapsulation layer 106 may include a different material from the underfill 107. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded.

Stage 5 illustrates a state after a portion of the encapsulation layer 106 is removed. A grinding process and/or a polishing process may be used to remove a top portion of the encapsulation layer 106. The grinding process and/or the polishing process may also remove back side portions of the integrated device(s). A top surface of the encapsulation layer 106 may be planar with a back side surface of the integrated device 103 and/or a back side surface of the integrated device 105.

Stage 6 illustrates a state after a plurality of solder interconnects 192 are coupled to the metallization portion 102. A solder reflow process may be used to couple the plurality of solder interconnects 192 to the plurality of metallization interconnects 121 of the metallization portion 102. Stage 6 may illustrate an example of the package 100.

### Exemplary Flow Diagram of a Method for Fabricating a Package Comprising an Alignment Structure

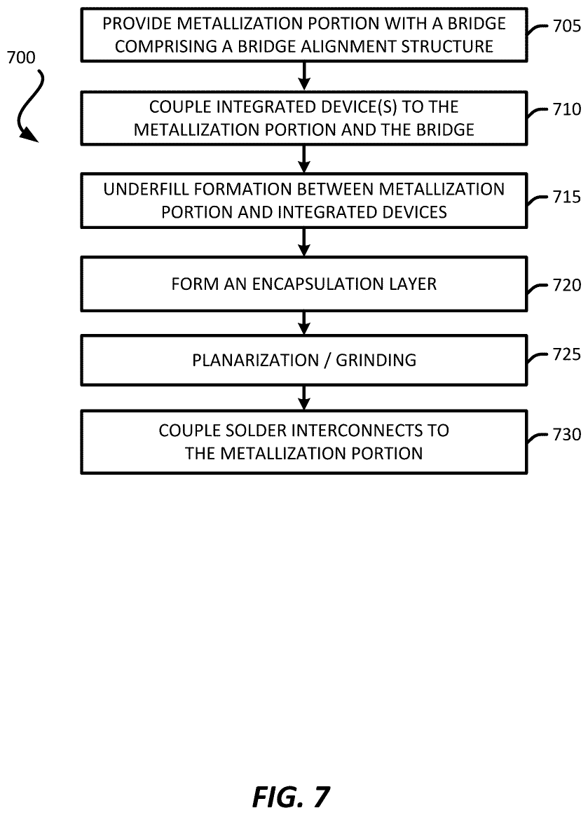

In some implementations, fabricating a package includes several processes. FIG. 7 illustrates an exemplary flow diagram of a method 700 for providing or fabricating a package. In some implementations, the method 700 of FIG. 7 may be used to provide or fabricate the package 100 described in the disclosure. However, the method 700 may be used to provide or fabricate any of the packages described in the disclosure.

It should be noted that the method 700 of FIG. 7 may combine one or more processes in order to simplify and/or clarify the method for providing or fabricating a package. In some implementations, the order of the processes may be changed or modified.

The method provides (at 705) a metallization portion that includes a bridge with an alignment structure. Stage 1 of FIG. 6A, illustrates and describes an example of a state after a metallization portion 102 is provided. The metallization portion 102 may include a bridge 101 that includes a bridge alignment structure 111. The bridge 101 may be located at least partially in the metallization portion 102. The metallization portion 102 may include at least one dielectric layer 120 and a plurality of metallization interconnects 121. An example of a process for fabricating a metallization portion 102 that includes the bridge 101 is illustrated and described below in at least FIGS. 8A-8B.

The method places and couples (at 710) integrated devices to the metallization portion and the bridge. Stage 2 of FIG. 6A, illustrates and describes an example of a state after the integrated device 103 and the integrated device 105 are coupled to the metallization portion 102 and the bridge 101. The integrated device 103 includes an alignment structure 131. The alignment structure 131 and the bridge alignment structure 111 help align the integrated device 103 with the metallization portion 102 and the bridge 101 during placement and coupling of the integrated device 103 to the metallization portion 102 and the bridge 101. The integrated device 103 may be coupled to the metallization portion 102 and the bridge 101 through a plurality of pillar interconnects 130 and a plurality of solder interconnects 135. A solder reflow process may be used to couple the integrated device 103 to the plurality of pillar interconnects 130 and the plurality of solder interconnects 135.

The integrated device 105 includes an alignment structure 151. The alignment structure 151 and the bridge alignment structure 111 help align the integrated device 105 with the metallization portion 102 and the bridge 101 during placement and coupling of the integrated device 105 to the metallization portion 102 and the bridge 101. The integrated device 105 may be coupled to the metallization portion 102 and the bridge 101 through a plurality of pillar interconnects 150 and a plurality of solder interconnects 155. A solder reflow process may be used to couple the integrated device 105 to the plurality of pillar interconnects 150 and the plurality of solder interconnects 155.

The method provides (at 715) an underfill between (i) the integrated devices and (ii) the metallization portion and the bridge. Stage 3 of FIG. 6A, illustrates and describes an example of a state after an underfill 107 is provided, formed and/or dispensed. The underfill 107 may be formed between (i) the integrated device 103 and (ii) the metallization portion 102 and the bridge 101. The underfill 107 may be formed between (i) the integrated device 105 and (ii) the metallization portion 102 and the bridge 101. The underfill 107 may be located between the integrated device 103 and the integrated device 105. The underfill 107 may at least partially encapsulate the plurality of pillar interconnects 130, the plurality of solder interconnects 135, the plurality of pillar interconnects 150, the plurality of solder interconnects 155, the alignment structure 131 and/or the alignment structure 151.

The method forms (at 720) an encapsulation layer that at least partially encapsulates the integrated devices. Stage 4 of FIG. 6B, illustrates and describes an example of a state after an encapsulation layer 106 is formed. The encapsulation layer 106 may at least partially encapsulate the integrated device 103, the integrated device 105 and/or the underfill 107. The encapsulation layer 106 may be coupled to the metallization portion 102. The encapsulation layer 106 may include a different material from the underfill 107. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded.

The method planarizes (at 725) the encapsulation layer. Stage 5 of FIG. 6B illustrates and describes an example of a state after a portion of the encapsulation layer 106 is removed. A grinding process and/or a polishing process may be used to remove a top portion of the encapsulation layer 106. The grinding process and/or the polishing process may also remove back side portions of the integrated device(s). A top surface of the encapsulation layer 106 may be planar with a back side surface of the integrated device 103 and/or a back side surface of the integrated device 105.

The method couples (at 730) a plurality of solder interconnects to the metallization portion. Stage 6 of FIG. 6B, illustrates and describes an example of a state after a plurality of solder interconnects 192 are coupled to the metallization portion 102. A solder reflow process may be used to couple the plurality of solder interconnects 192 to the plurality of metallization interconnects 121 of the metallization portion 102. Stage 6 may illustrate an example of the package 100.

### Exemplary Sequence for Fabricating a Metallization Portion Comprising a Bridge

In some implementations, fabricating a metallization portion includes several processes. FIGS. 8A-8B illustrate an exemplary sequence for providing or fabricating a metallization portion. In some implementations, the sequence of FIGS. 8A-8B may be used to provide or fabricate the metallization portion 102. However, the process of FIGS. 8A-8B may be used to fabricate any of the metallization portions described in the disclosure.

It should be noted that the sequence of FIGS. 8A-8B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 8A, illustrates a state after a carrier 800 is provided. A seed layer 801 may be located over the carrier 800. The carrier 800 may be replaced with other components and/or materials.

Stage 2 illustrates a state after the bridge 101 is placed on the carrier 800 and/or the seed layer 801. An adhesive may be used to couple the bridge 101 to the carrier 800 and/or the seed layer 801. In some implementations, a front side of the bridge 101 is placed on the carrier 800. The front side of the bridge 101 may be a side of the bridge 101 that includes the bride interconnects. In some implementations, the bridge 101 may include a bridge alignment structure 111 or a bridge alignment structure with a shorter height.

Stage 3 illustrates a state after a plurality of interconnects 812 are formed. The interconnects 812 may be located over the seed layer 801. A lithography process, a plating process, a strip process and/or an etching process may be used to form the plurality of interconnects 812.

Stage 4 illustrates a state after a dielectric layer 810 is formed over the carrier 800, the bridge 101, the seed layer 801 and the plurality of interconnects 812. A deposition and/or lamination process may be used to form the dielectric layer 810. The dielectric layer 810 may include prepreg and/or polyimide. The dielectric layer 810 may include a photo-imageable dielectric. However, different implementations may use different materials for the dielectric layer.

Stage 5 illustrates a state after a plurality of cavities 813 are formed in the dielectric layer 810. The plurality of cavities 813 may be formed using an etching process (e.g., photo etching process), a laser process, an exposure process and/or a development process. The plurality of cavities 813 may be openings in a dielectric layer.

Stage 6 illustrates a state after interconnects 822 are formed in and over the dielectric layer 810, including in and over the plurality of cavities 813. For example, a via, pad and/or traces may be formed. A lithography process, a plating process, a strip process and/or an etching process may be used to form the interconnects.

Stage 7, as shown in FIG. 8B, illustrates a state after a dielectric layer 820 is formed over the dielectric layer 810 and the plurality of interconnects 822. A deposition and/or lamination process may be used to form the dielectric layer 820. The dielectric layer 820 may include prepreg and/or polyimide. The dielectric layer 820 may include a photo-imageable dielectric. However, different implementations may use different materials for the dielectric layer.

Stage 8, illustrates a state after a plurality of cavities 823 are formed in the dielectric layer 120. The dielectric layer 120 may represent the dielectric layer 810 and/or the dielectric layer 820. The plurality of cavities 823 may be formed using an etching process (e.g., photo etching process), a laser process, an exposure process and/or a development process. The plurality of cavities 823 may be openings in a dielectric layer.

Stage 9 illustrates a state after interconnects 832 are formed in and over the dielectric layer 120, including in and over the plurality of cavities 823. For example, a via, pad and/or traces may be formed. A lithography process, a plating process, a strip process and/or an etching process may be used to form the interconnects.

Stage 10 illustrates a state after the carrier 800 and the seed layer 801 are removed and/or etched out. The carrier 800 and the seed layer 801 may be decoupled and/or separated from the dielectric layer 120 and the plurality of metallization interconnects 121. In some implementations, any adhesive (e.g., adhesive that is used to couple bridge to the carrier and/or the seed layer) may also be removed. The plurality of metallization interconnects 121 may represent a plurality of interconnects 812, the plurality of interconnects 822 and/or the plurality of interconnects 832.

Stage 11 illustrates a state after the bridge alignment structure 111 is formed. The bridge alignment structure 111 may be formed on the bridge 101. The bridge alignment structure 111 may be formed in addition to the alignment structure that may already be on the bridge 101. In some implementations, forming the bridge alignment structure 111 may include increasing the thickness and/or height of the bridge alignment structure 111. In some implementations, a plating process may be used to form the bridge alignment structure 111. Stage 11 may illustrates an example of a metallization portion that includes an alignment structure.

It is noted that the bridge 101 may be coupled to the metallization portion during a different stage of the fabrication process of the metallization portion. For example, the bridge 101 may be coupled (e.g., coupled through an adhesive) to a cavity in the metallization portion, after the metallization portion and the cavity are formed. Thus, the bridge 101 may be embedded in the metallization portion towards the end stage of the fabrication process of the metallization portion.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion Comprising a Bridge

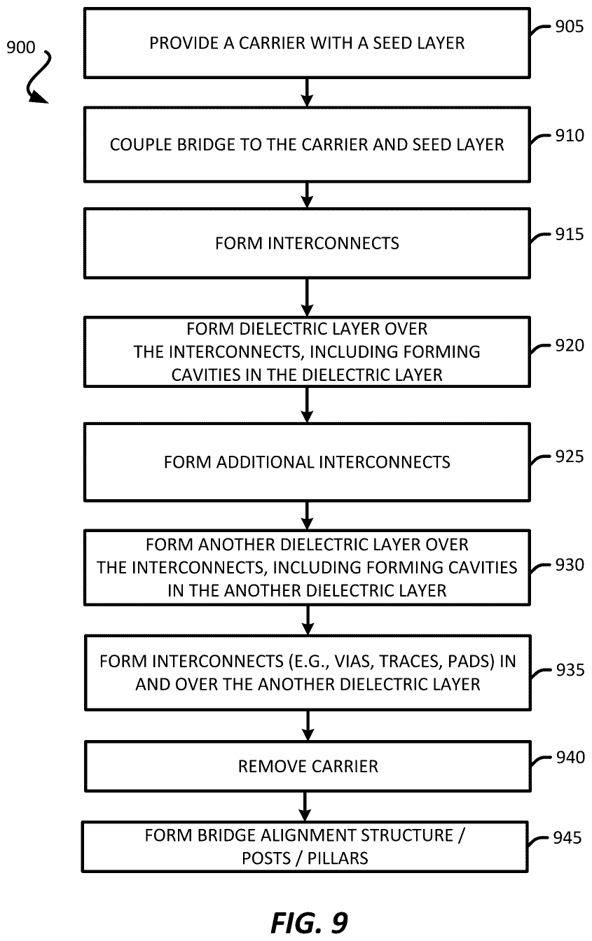

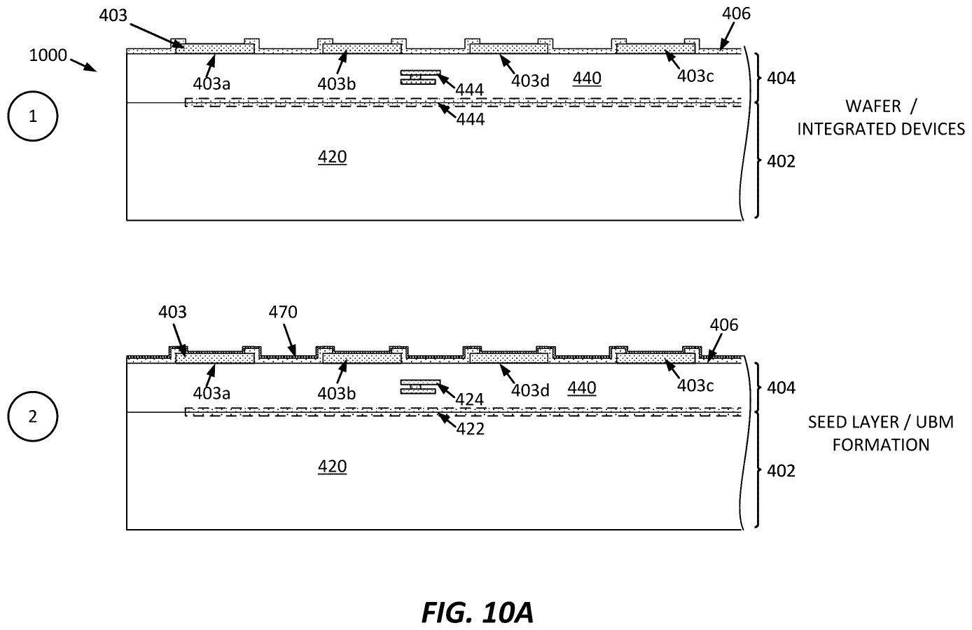

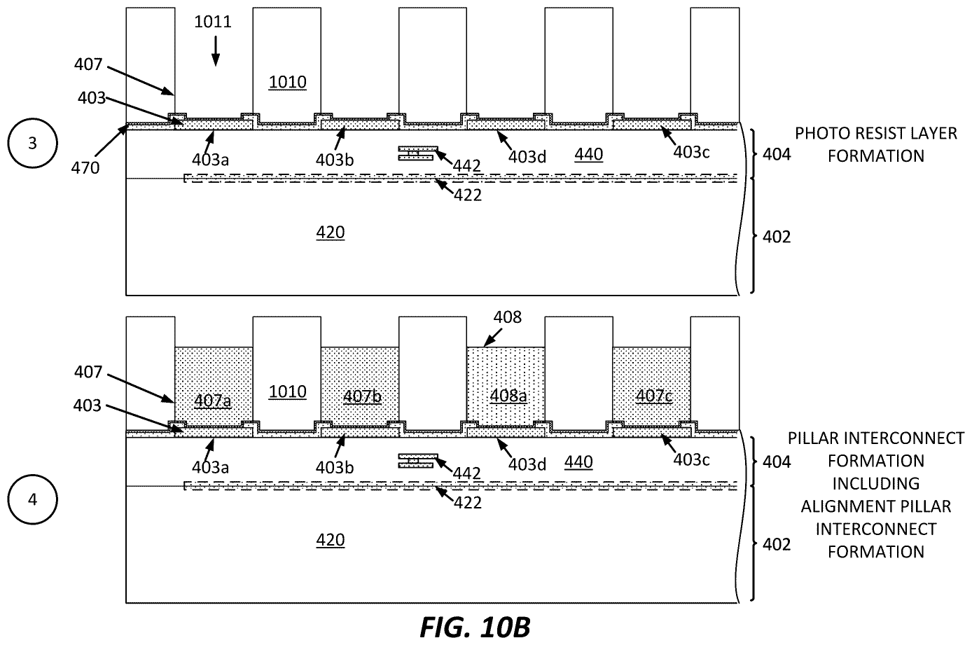

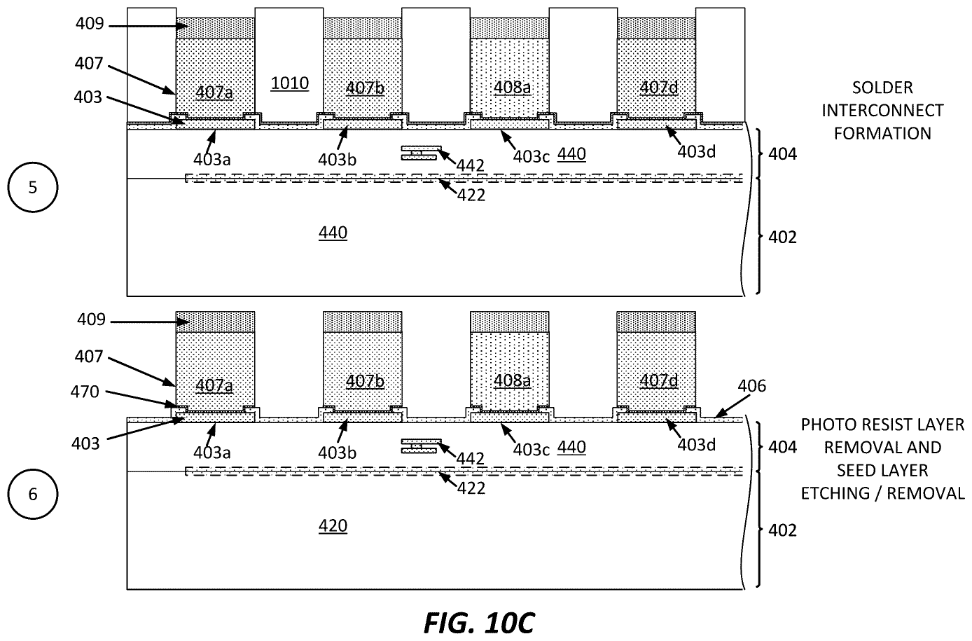

In some implementations, fabricating a metallization portion includes several processes. FIG. 9 illustrates an exemplary flow diagram of a method 900 for providing or fabricating a metallization portion. In some implementations, the method 900 of FIG. 10 may be used to provide or fabricate any of the metallization portions of the disclosure. For example, the method 900 of FIG. 9 may be used to fabricate the metallization portion 102 with a bridge.

It should be noted that the method 900 of FIG. 9 may combine one or more processes in order to simplify and/or clarify the method for providing or fabricating a metallization portion. In some implementations, the order of the processes may be changed or modified.

The method provides (at 905) a carrier with a seed layer. Stage 1 of FIG. 8A, illustrates and describes an example of a state after a carrier 800 is provided. A seed layer 801 may be located over the carrier 800. The carrier 800 may be replaced with other components and/or materials.

The method places and couples (at 910) a bridge to the carrier and/or the seed layer. Stage 2 of FIG. 8A, illustrates and describes an example of a state after the bridge 101 is placed on the carrier 800 and/or the seed layer 801. An adhesive may be used to couple the bridge 101 to the carrier 800 and/or the seed layer 801. The bridge 101 may include a bridge alignment structure 111 or an alignment structure with a shorter height.

The method forms (at 915) interconnects on the carrier and/or the seed layer. Stage 3 of FIG. 8A, illustrates a state after a plurality of interconnects 812 are formed. The interconnects 812 may be located over the seed layer 801. A lithography process, a plating process, a strip process and/or an etching process may be used to form the plurality of interconnects 812.

The method forms (at 920) a dielectric layer. Stage 4 of FIG. 8A, illustrates and describes an example of a state after a dielectric layer 810 is formed over the carrier 800, the bridge 101, the seed layer 801 and the plurality of interconnects 812. A deposition and/or lamination process may be used to form the dielectric layer 810. The dielectric layer 810 may include prepreg and/or polyimide. The dielectric layer 810 may include a photo-imageable dielectric. However, different implementations may use different materials for the dielectric layer.

The method may also form (at 920) cavities in the dielectric layer. Stage 5 of FIG. 8A, illustrates and describes an example of a state after a plurality of cavities 813 are formed in the dielectric layer 810. The plurality of cavities 813 may be formed using an etching process (e.g., photo etching process), a laser process, an exposure process and/or a development process. The plurality of cavities 813 may be openings in a dielectric layer.

The method forms (at 925) interconnects. Stage 6 of FIG. 8A, illustrates and describes an example of a state after interconnects 822 are formed in and over the dielectric layer 810, including in and over the plurality of cavities 813. For example, a via, pad and/or traces may be formed. A lithography process, a plating process, a strip process and/or an etching process may be used to form the interconnects.

The method forms (at 930) another dielectric layer. Stage 7 of FIG. 8B, illustrates and describes an example of a state after a dielectric layer 820 is formed over the dielectric layer 810 and the plurality of interconnects 822. A deposition and/or lamination process may be used to form the dielectric layer 820. The dielectric layer 820 may include prepreg and/or polyimide. The dielectric layer 820 may include a photo-imageable dielectric. However, different implementations may use different materials for the dielectric layer.

The method may also form (at 930) cavities in the another dielectric layer. Stage 8 of FIG. 8B, illustrates and describes an example of a state after a plurality of cavities 823 are formed in the dielectric layer 120. The dielectric layer 120 may represent the dielectric layer 810 and/or the dielectric layer 820. The plurality of cavities 823 may be formed using an etching process (e.g., photo etching process), a laser process, an exposure process and/or a development process. The plurality of cavities 823 may be openings in a dielectric layer.

The method forms (at 935) additional interconnects. Stage 9 of FIG. 8B, illustrates and describes an example of a state after interconnects 832 are formed in and over the dielectric layer 120, including in and over the plurality of cavities 823. For example, a via, pad and/or traces may be formed. A lithography process, a plating process, a strip process and/or an etching process may be used to form the interconnects.

The method removes (at 940) the carrier and/or the seed layer. Stage 10 of FIG. 8B, illustrates and describes an example of a state after the carrier 800 and the seed layer 801 are removed and/or etched out. The carrier 800 and the seed layer 801 may be decoupled and/or separated from the dielectric layer 120 and the plurality of metallization interconnects 121. The plurality of metallization interconnects 121 may represent a plurality of interconnects 812, the plurality of interconnects 822 and/or the plurality of interconnects 832.

The method forms (at 945) the alignment structure and/or additional alignment structure for the bridge. Stage 11 of FIG. 8B, illustrates and describes an example of a state after the bridge alignment structure 111 is formed. The bridge alignment structure 111 may be formed on the bridge 101. The bridge alignment structure 111 may be formed in addition to the alignment structure that may already be on the bridge 101. In some implementations, forming the bridge alignment structure 111 may include increasing the thickness and/or height of the bridge alignment structure 111. In some implementations, a plating process may be used to form the bridge alignment structure 111. Stage 11 may illustrates an example of a metallization portion that includes an alignment structure.

It is noted that the bridge 101 may be coupled to the metallization portion during a different stage of the fabrication process of the metallization portion. For example, the bridge 101 may be coupled (e.g., coupled through an adhesive) to a cavity in the metallization portion, after the metallization portion and the cavity are formed. Thus, the bridge 101 may be embedded in the metallization portion towards the end stage of the fabrication process of the metallization portion.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating an Integrated Device Comprising an Alignment Structure

In some implementations, fabricating an integrated device includes several processes. FIGS. 10A-10C illustrate an exemplary sequence for providing or fabricating an integrated device comprising an alignment structure. In some implementations, the sequence of FIGS. 10A-10C may be used to provide or fabricate the integrated device 400. However, the process of FIGS. 10A-10C may be used to fabricate any integrated device described in the disclosure.

It should be noted that the sequence of FIGS. 10A-10C may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure.

Stage 1, as shown in FIG. 10A, illustrates a state after a wafer 1000 is provided. The wafer 1000 may include one or more un-diced integrated devices. The wafer 1000 may include a die substrate portion 2402, a die interconnection portion 404, a plurality of pad interconnects 403, a passivation layer 406, as described above in at least FIG. 4.

Stage 2 illustrates a state after a seed layer is formed over the wafer 1000. The seed layer 470 may be an under bump metallization interconnect. The seed layer 470 may be formed over the passivation layer 406 and the plurality of pad interconnects 403. The seed layer may include copper (Cu). A sputtering process may be used to form the seed layer 470.

Stage 3, as shown in FIG. 10B, illustrates a state after a photo resist layer 1010 is formed over the wafer 1000. For example, the photo resist layer 1010 may be formed over the seed layer 470 (e.g., over the under bump metallization interconnect). The photo resist layer 1010 may be patterned to include a plurality of openings 1011 in the photo resist layer 1010. The photo resist layer 1010 may be coated over the wafer 1000. A photolithography process may be used to form and define the pattern of the photo resist layer 1010. For example, an exposure process and development process may be used to form the plurality of openings 1011 in the photo resist layer 1010. The plurality of openings 1011 may be located over the plurality of pad interconnects 403.

Stage 4 illustrates a state after the plurality of pillar interconnects 407 and at least one pillar interconnect 408 are formed and coupled to the seed layer 470. The at least one pillar interconnect 408 may configured as an alignment pillar that is part of an alignment structure. A plating process may be used to form the plurality of pillar interconnects 407 and the at least one pillar interconnect 408. The plurality of pillar interconnects 407 and the at least one pillar interconnect 408 may be formed in the plurality of openings 1011 of the photo resist layer 1010. The pillar interconnect 407a may be coupled to the pad interconnect 403a, through the seed layer 470. The pillar interconnect 407b may be coupled to the pad interconnect 403b, through the seed layer 470. The pillar interconnect 407c may be coupled to the pad interconnect 403c, through the seed layer 470. The pillar interconnect 408a may be coupled to the pad interconnect 403d, through the seed layer 470.

Stage 5, as shown in FIG. 10C, illustrates a state after at least one solder interconnect from the plurality of solder interconnects 409 are formed and coupled to the plurality of pillar interconnects 407 and the at least one pillar interconnect 408. A pasting process may be used to form the plurality of solder interconnects 409 in openings of the photo resist layer 1010.

Stage 6 illustrates a state after the photo resist layer 1010 is removed. Stage 6 also illustrates a state after portions of the seed layer 470 are removed. An etching process may be used to remove portions of the seed layer 470. The portions of the seed layer 470 that are removed are portions that are not covered by the plurality of pillar interconnects 407 and/or the at least one pillar interconnect 408. Stage 6 may illustrate an example of the integrated device 400.

### Exemplary Flow Diagram of a Method for Fabricating an Integrated Device Comprising an Alignment Structure

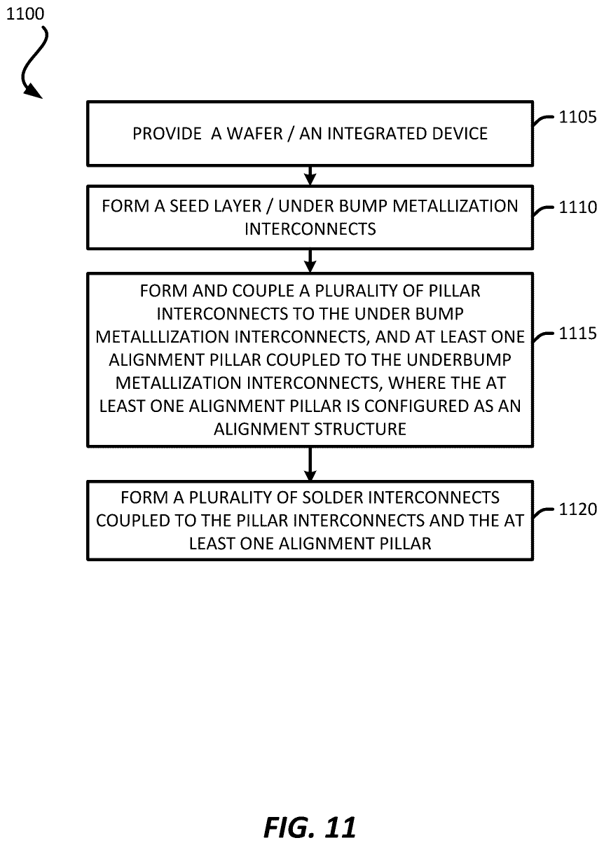

In some implementations, fabricating an integrated device includes several processes. FIG. 11 illustrates an exemplary flow diagram of a method 1100 for providing or fabricating an integrated device that includes an alignment structure In some implementations, the method 1100 of FIG. 11 may be used to provide or fabricate the integrated device of the disclosure. For example, the method 1100 of FIG. 11 may be used to fabricate the integrated device 400.

It should be noted that the method 1100 of FIG. 11 may combine one or more processes in order to simplify and/or clarify the method for providing or fabricating an integrated device. In some implementations, the order of the processes may be changed or modified.

The method provides (at 1105) a wafer comprising an integrated device. Stage 1 of FIG. 10A, illustrates and describes an example of a state after a wafer 1000 is provided. The wafer 1000 may include a die substrate portion 2402, a die interconnection portion 404, a plurality of pad interconnects 403, a passivation layer 406, as described above in at least FIG. 4.

The method forms (at 1110) a seed layer. Stage 2 of FIG. 10A, illustrates and describes an example of a state after a seed layer is formed over the wafer 1000. The seed layer 470 may be an under bump metallization interconnect. The seed layer 470 may be formed over the passivation layer 406 and the plurality of pad interconnects 403. The seed layer may include copper (Cu). A sputtering process may be used to form the seed layer 470.

The method forms (at 1115) a plurality of pillar interconnects and at least one pillar interconnect configured as an alignment pillar. Stage 3 of FIG. 10B, illustrates and describes an example of a state after a photo resist layer 1010 is formed over the wafer 1000. For example, the photo resist layer 1010 may be formed over the seed layer 470 (e.g., over the under bump metallization interconnect). The photo resist layer 1010 may be patterned to include a plurality of openings 1011 in the photo resist layer 1010. The photo resist layer 1010 may be coated over the wafer 1000. A photolithography process may be used to form and define the pattern of the photo resist layer 1010. For example, an exposure process and development process may be used to form the plurality of openings 1011 in the photo resist layer 1010. The plurality of openings 1011 may be located over the plurality of pad interconnects 403.

Stage 4 of FIG. 10B, illustrates and describes an example of a state after the plurality of pillar interconnects 407 and at least one pillar interconnect 408 are formed and coupled to the seed layer 470. The at least one pillar interconnect 408 may configured as an alignment pillar that is part of an alignment structure. A plating process may be used to form the plurality of pillar interconnects 407 and the at least one pillar interconnect 408. The plurality of pillar interconnects 407 and the at least one pillar interconnect 408 may be formed in the plurality of openings 1011 of the photo resist layer 1010. The pillar interconnect 407a may be coupled to the pad interconnect 403a, through the seed layer 470. The pillar interconnect 407b may be coupled to the pad interconnect 403b, through the seed layer 470. The pillar interconnect 407c may be coupled to the pad interconnect 403c, through the seed layer 470. The pillar interconnect 408a may be coupled to the pad interconnect 403d, through the seed layer 470.

The method forms and couples (at 1120) a plurality of solder interconnects to the plurality of pillar interconnects and the at least one alignment pillar. Stage 5 of FIG. 10C, illustrates and describes an example of a state after at least one solder interconnect from the plurality of solder interconnects 409 are formed and coupled to the plurality of pillar interconnects 407 and the at least one pillar interconnect 408. A pasting process may be used to form the plurality of solder interconnects 409 in openings of the photo resist layer 1010.

The method may remove a photo resist layer after forming the plurality of solder interconnects. Stage 6 of FIG. 10C, illustrates and describes an example of a state after the photo resist layer 1010 is removed. Stage 6 also illustrates a state after portions of the seed layer 470 are removed. An etching process may be used to remove portions of the seed layer 470. The portions of the seed layer 470 that are removed are portions that are not covered by the plurality of pillar interconnects 407 and/or the at least one pillar interconnect 408. Stage 6 may illustrate an example of the integrated device 400.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Bridge Comprising a Bridge Alignment Structure

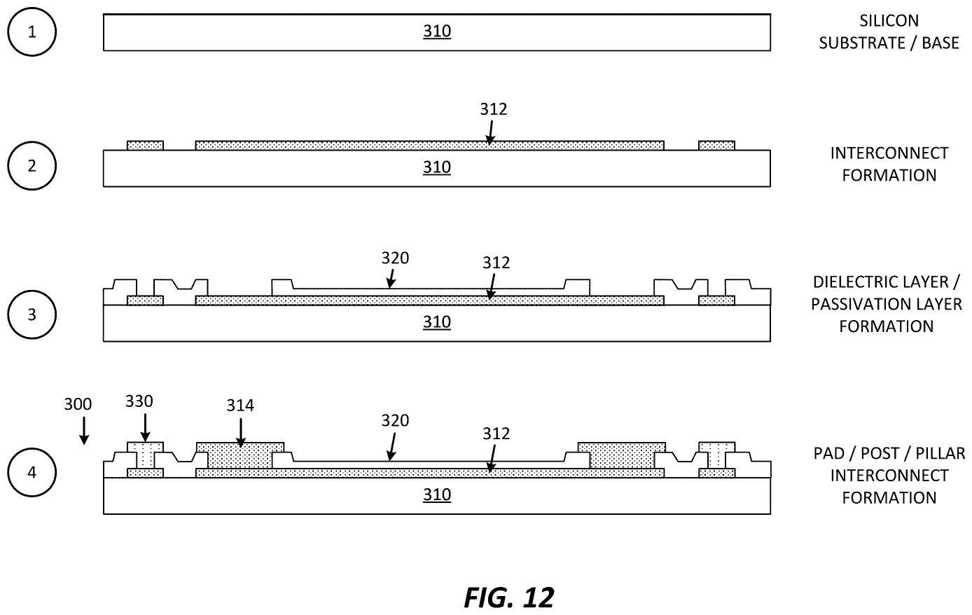

In some implementations, fabricating a bridge includes several processes. FIG. 12 illustrates an exemplary sequence for providing or fabricating a bridge comprising a bridge alignment structure. In some implementations, the sequence of FIG. 12 may be used to provide or fabricate the bridge 300. However, the process of FIG. 12 may be used to fabricate any bridge described in the disclosure.

It should be noted that the sequence of FIG. 12 may combine one or more stages in order to simplify and/or clarify the sequence for providing or fabricating a bridge. In some implementations, the order of the processes may be changed or modified. In some implementations, one or more of processes may be replaced or substituted without departing from the scope of the disclosure.

Stage 1, as shown in FIG. 12, illustrates a state after a bridge substrate 310 is provided. The bridge substrate 310 may be a silicon substrate and/or silicon base.

Stage 2 illustrates a state after a plurality of bridge interconnects 312 are formed. A lithography process, a plating process, a strip process and/or an etching process may be used to form the bridge interconnects.

Stage 3 illustrates a state after a dielectric layer 320 is formed. The dielectric layer 320 may be a passivation layer. The dielectric layer 320 may be formed and deposed on the bridge substrate 310 and/or the plurality of bridge interconnects 312. The dielectric layer 320 may include a plurality of openings. A deposition process and/or a lamination process may be used to form the dielectric layer 320.

Stage 4 illustrates a state after a plurality of bridge interconnects 314 and a bridge alignment structure 330 are formed. A lithography process, a plating process, a strip process and/or an etching process may be used to form the bridge interconnects and the bridge alignment structure 330. The plurality of bridge interconnects 314 may be coupled to the plurality of bridge interconnects 312. In some implementations, an additional plating process may be used to increase the thickness and/or the height of the bridge alignment structure 330. In some implementations, the bridge alignment structure 330 may include at least one bridge alignment pillar. Stage 4 may illustrate an example of a bridge with a bridge alignment structure or a bridge alignment structure with a lower height.

### Exemplary Flow Diagram of a Method for Fabricating a Bridge Comprising a Bridge Alignment Structure

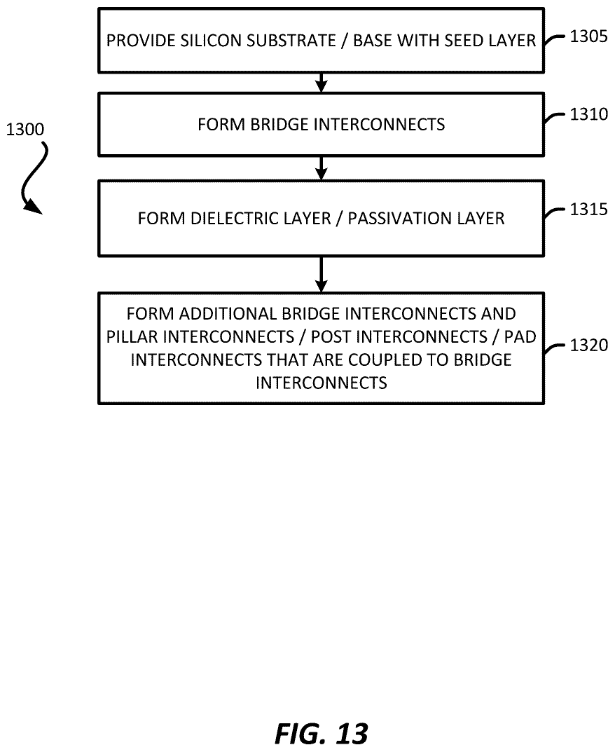

In some implementations, fabricating a bridge includes several processes. FIG. 13 illustrates an exemplary flow diagram of a method 1300 for providing or fabricating a bridge that includes a bridge alignment structure In some implementations, the method 1300 of FIG. 13 may be used to provide or fabricate the bridge of the disclosure. For example, the method 1300 of FIG. 13 may be used to fabricate the bridge 300.

It should be noted that the method 1300 of FIG. 13 may combine one or more processes in order to simplify and/or clarify the method for providing or fabricating a bridge. In some implementations, the order of the processes may be changed or modified.

The method provides (at 1305) a bridge substrate. Stage 1 of FIG. 12, illustrates and describes an example of a state after a bridge substrate 310 is provided. The bridge substrate 310 may be a silicon substrate and/or silicon base.

The method forms (at 1310) a plurality of bridge interconnects. Stage 2 of FIG. 12, illustrates and describes an example of a state after a plurality of bridge interconnects 312 are formed. A lithography process, a plating process, a strip process and/or an etching process may be used to form the bridge interconnects.

The method forms (at 1315) a dielectric layer. Stage 3 of FIG. 12, illustrates and describes an example of a state after a dielectric layer 320 is formed. The dielectric layer 320 may be a passivation layer. The dielectric layer 320 may be formed and deposed on the bridge substrate 310 and/or the plurality of bridge interconnects 312. The dielectric layer 320 may include a plurality of openings. A deposition process and/or a lamination process may be used to form the dielectric layer 320.

The method forms (at 1320) a plurality of bridge interconnects, including pillar interconnects, and a bridge alignment structure, which may include a bridge alignment pillar. Stage 4 of FIG. 12, illustrates and describes an example of a state after a plurality of bridge interconnects 314 and a bridge alignment structure 330 are formed. A lithography process, a plating process, a strip process and/or an etching process may be used to form the bridge interconnects and the bridge alignment structure 330. The plurality of bridge interconnects 314 may be coupled to the plurality of bridge interconnects 312. In some implementations, an additional plating process may be used to increase the thickness and/or the height of the bridge alignment structure 330. In some implementations, the bridge alignment structure 330 may include at least one bridge alignment pillar. Stage 4 may illustrate an example of a bridge with a bridge alignment structure or a bridge alignment structure with a lower height.

### Exemplary Electronic Devices

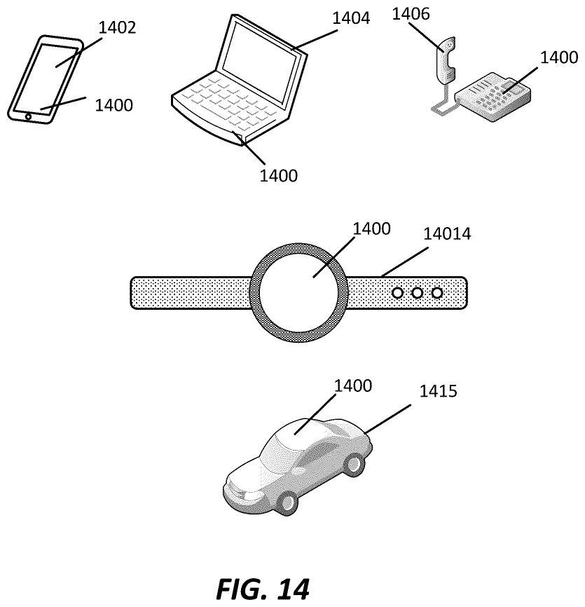

FIG. 14 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1402, a laptop computer device 1404, a fixed location terminal device 1406, a wearable device 1408, or automotive vehicle 1410 may include a device 1400 as described herein. The device 1400 may be, for example, any of the devices and/or integrated circuit (IC) packages described herein. The devices 1402, 1404, 1406 and 1408 and the vehicle 1410 illustrated in FIG. 14 are merely exemplary. Other electronic devices may also feature the device 1400 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-5, 6A-6B, 7, 8A-8B, 9, 10A-10C and 11-14 may be rearranged and/or combined into a single component, process, feature or function or embodied in several components, processes, or functions. Additional elements, components, processes, and/or functions may also be added without departing from the disclosure. It should also be noted FIGS. 1-5, 6A-6B, 7, 8A-8B, 9, 10A-10C and 11-14 and its corresponding description in the present disclosure is not limited to dies and/or ICs. In some implementations, FIGS. 1-5, 6A-6B, 7, 8A-8B, 9, 10A-10C and 11-14 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a metallization portion comprising at least one dielectric layer; and a plurality of metallization interconnects; a bridge comprising a bridge alignment structure, wherein the bridge is located at least partially in the metallization portion; a first integrated device coupled to the bridge and the metallization portion; and a second integrated device coupled to the bridge and the metallization portion.

Aspect 2: The package of aspect 1, wherein the first integrated device comprises a first alignment structure.

Aspect 3: The package of aspect 2, wherein the first alignment structure of the first integrated device is adjacent to the bridge alignment structure of the bridge.

Aspect 4: The package of aspect 3, wherein the bridge alignment structure comprises a first bridge alignment pillar and a second bridge alignment pillar, and wherein the first alignment structure of the first integrated device is located laterally between the first bridge alignment pillar of the bridge and the second bridge alignment pillar of the bridge.

Aspect 5: The package of aspects 2 through 4, wherein the second integrated device comprises a second alignment structure.

Aspect 6: The package of aspect 5, wherein the bridge alignment structure comprises a first bridge alignment pillar and a second bridge alignment pillar, wherein the first alignment structure of the first integrated device is adjacent to the first bridge alignment pillar of the bridge, and wherein the second alignment structure of the second integrated device is adjacent to the second bridge alignment pillar of the bridge.

Aspect 7: The package of aspect 6, wherein the bridge alignment structure further comprises a third bridge alignment pillar, and wherein the first alignment structure of the first integrated device is located laterally between the first bridge alignment pillar of the bridge and the third bridge alignment pillar of the bridge.

Aspect 8: The package of aspects 2 through 7, wherein the first alignment structure comprises a first alignment pillar.

Aspect 9: The package of aspects 1 through 8, wherein the first integrated device is coupled to the bridge and the metallization portion through a first plurality of pillar interconnects and a first plurality of solder interconnects.

Aspect 10: The package of aspect 9, wherein the second integrated device is coupled to the bridge and the metallization portion through a second plurality of pillar interconnects and a second plurality of solder interconnects.

Aspect 11: The package of aspect 9, wherein the first integrated device comprises a first alignment pillar that is coupled to the bridge through a solder interconnect.

Aspect 12: The package of aspect 11, wherein the first alignment pillar is coupled to a pad interconnect of the bridge.

Aspect 13: The package of aspects 11 through 12, wherein the first alignment pillar touches the bridge alignment structure.

Aspect 14: The package of aspects 11 through 13, wherein the first alignment pillar is free of an electrical connection with transistors of the first integrated device.

Aspect 15: The package of aspects 1 through 14, wherein the bridge alignment structure is free of an electrical connection with transistors of the first integrated device.

Aspect 16: A package comprising a metallization portion comprising at least one dielectric layer; and a plurality of metallization interconnects; a bridge located at least partially in the metallization portion; a first integrated device coupled to the bridge and the metallization portion, wherein the first integrated device comprises a first alignment structure; and a second integrated device coupled to the bridge and the metallization portion.

Aspect 17: The package of aspect 16, wherein the second integrated device comprises a second alignment structure.

Aspect 18: The package of aspect 17, wherein the bridge comprises a bridge alignment structure.

Aspect 19: The package of aspect 18, wherein the first alignment structure of the first integrated device is adjacent to the bridge alignment structure of the bridge, and wherein the second alignment structure of the first integrated device is adjacent to the bridge alignment structure of the bridge.

Aspect 20: The package of aspect 19, wherein the bridge alignment structure comprises a first bridge alignment pillar, a second bridge alignment pillar, a third bridge alignment pillar and a fourth bridge alignment pillar, wherein the first alignment structure of the first integrated device is located laterally between the first bridge alignment pillar of the bridge and the second bridge alignment pillar of the bridge, and wherein the second alignment structure of the second integrated device is located laterally between the third bridge alignment pillar of the bridge and the fourth bridge alignment pillar of the bridge.

Aspect 21: The package of aspects 1 through 20, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a metallization portion comprising:
at least one dielectric layer; and
a plurality of metallization interconnects;
a bridge comprising a bridge alignment structure, wherein the bridge is located at least partially in the metallization portion;
a first integrated device coupled to the bridge and the metallization portion; and
a second integrated device coupled to the bridge and the metallization portion.

2. The package of claim 1, wherein the first integrated device comprises a first alignment structure.

3. The package of claim 2, wherein the first alignment structure of the first integrated device is adjacent to the bridge alignment structure of the bridge.

4. The package of claim 3,
wherein the bridge alignment structure comprises a first bridge alignment pillar and a second bridge alignment pillar, and
wherein the first alignment structure of the first integrated device is located laterally between the first bridge alignment pillar of the bridge and the second bridge alignment pillar of the bridge.

5. The package of claim 2, wherein the second integrated device comprises a second alignment structure.

6. The package of claim 5,
wherein the bridge alignment structure comprises a first bridge alignment pillar and a second bridge alignment pillar,
wherein the first alignment structure of the first integrated device is adjacent to the first bridge alignment pillar of the bridge, and
wherein the second alignment structure of the second integrated device is adjacent to the second bridge alignment pillar of the bridge.

7. The package of claim 6,
wherein the bridge alignment structure further comprises a third bridge alignment pillar, and
wherein the first alignment structure of the first integrated device is located laterally between the first bridge alignment pillar of the bridge and the third bridge alignment pillar of the bridge.

8. The package of claim 2, wherein the first alignment structure comprises a first alignment pillar.

9. The package of claim 1, wherein the first integrated device is coupled to the bridge and the metallization portion through a first plurality of pillar interconnects and a first plurality of solder interconnects.

10. The package of claim 9, wherein the second integrated device is coupled to the bridge and the metallization portion through a second plurality of pillar interconnects and a second plurality of solder interconnects.

11. The package of claim 9, wherein the first integrated device comprises a first alignment pillar that is coupled to the bridge through a solder interconnect.

12. The package of claim 11, wherein the first alignment pillar is coupled to a pad interconnect of the bridge.

13. The package of claim 11, wherein the first alignment pillar touches the bridge alignment structure.

14. The package of claim 11, wherein the first alignment pillar is free of an electrical connection with transistors of the first integrated device.

15. The package of claim 1, wherein the bridge alignment structure is free of an electrical connection with transistors of the first integrated device.

16. A package comprising:
a metallization portion comprising:
at least one dielectric layer; and
a plurality of metallization interconnects;
a bridge located at least partially in the metallization portion;
a first integrated device coupled to the bridge and the metallization portion, wherein the first integrated device comprises a first alignment structure; and
a second integrated device coupled to the bridge and the metallization portion.

17. The package of claim 16, wherein the second integrated device comprises a second alignment structure.

18. The package of claim 17, wherein the bridge comprises a bridge alignment structure.

19. The package of claim 18,
wherein the first alignment structure of the first integrated device is adjacent to the bridge alignment structure of the bridge, and
wherein the second alignment structure of the first integrated device is adjacent to the bridge alignment structure of the bridge.

20. The package of claim 19,
wherein the bridge alignment structure comprises a first bridge alignment pillar, a second bridge alignment pillar, a third bridge alignment pillar and a fourth bridge alignment pillar,
wherein the first alignment structure of the first integrated device is located laterally between the first bridge alignment pillar of the bridge and the second bridge alignment pillar of the bridge, and
wherein the second alignment structure of the second integrated device is located laterally between the third bridge alignment pillar of the bridge and the fourth bridge alignment pillar of the bridge.
